(19) United States
(12) Patent Application Publication
(10) Pub. No.: US 2023/0247821 A1
(43) Pub. Date: Aug. 3, 2023

(54) SEMICONDUCTOR DEVICE AND METHOD FOR FABRICATING THE SAME

(71) Applicant: SK hynix Inc., Gyeonggi-do (KR)

(72) Inventor: Se Han KWON, Gyeonggi-do (KR)

(21) Appl. No.: 17/838,488

(22) Filed: Jun. 13, 2022

(30) Foreign Application Priority Data
Dec. 30, 2021 (KR) 10-2021-0192466

(51) Int. Cl. H01L 27/108

(52) U.S. Cl. CPC H01L 27/10805; H01L 27/10885

(57) ABSTRACT

A semiconductor device may include a semiconductor pillar including a first sidewall and a second sidewall a semiconductor pillar including a first sidewall and a second sidewall facing each other; a bit line coupled to a lower portion of the semiconductor pillar; a capacitor coupled to an upper portion of the semiconductor pillar; a body line coupled to the first sidewall of the semiconductor pillar; and a vertical word line disposed over the second sidewall of the semiconductor pillar.

### CROSS-REFERENCE TO RELATED APPLICATIONS

The present application claims priority of Korean Patent Application No. 10-2021-0192466, filed on Dec. 30, 2021, which is incorporated herein by reference in its entirety.

### BACKGROUND

### 1. Field

Various embodiments of the present invention relate to a semiconductor device, and more particularly, to a semiconductor device including a bit line and a method for fabricating the semiconductor device.

### 2. Description of the Related Art

Most semiconductor devices include transistors. For example, in a memory device such as Dynamic Random Access Memory (DRAM), a memory cell includes a cell transistor.

Since memory devices are continuously required to have improved density and performance, a transistor forming technology faces physical limitation. For example, as the size of a memory cell decreases, the size of a transistor decreases as well. This inevitably reduces the channel length of a transistor. When the channel length of a transistor decreases, characteristics of a memory device deteriorates due to diverse problems, such as a decrease in data retention characteristics.

Recently, vertical channel transistors have been proposed. A vertical channel transistor (VCT) includes a pillar in which a vertical channel is formed.

### SUMMARY

Embodiments of the present invention are directed to a semiconductor device including a vertical channel transistor, and a method for fabricating the same.

In accordance with an embodiment of the present invention, a semiconductor device may include a semiconductor pillar including a first sidewall and a second sidewall facing each other; a bit line coupled to a lower portion of the semiconductor pillar; a capacitor coupled to an upper portion of the semiconductor pillar; a body line coupled to the first sidewall of the semiconductor pillar; and a vertical word line disposed over the second sidewall of the semiconductor pillar.

In accordance with another embodiment of the present invention, a semiconductor device may include a substrate; a peripheral circuit portion over the substrate; and a memory cell array including a bit line, a transistor, and a capacitor that are vertically stacked with respect to the peripheral circuit portion, wherein the transistor includes a semiconductor pillar disposed between the bit line and the capacitor; a body line coupled to a first sidewall of the semiconductor pillar; and a vertical word line disposed over a second sidewall of the semiconductor pillar.

In accordance with yet another embodiment of the present invention, a method for fabricating semiconductor device may include stacking a sacrificial layer and a semiconductor layer over a substrate; forming a merged semiconductor line by etching the semiconductor layer; forming a bit line isolation portion by etching the sacrificial layer below the merged semiconductor line and bit line openings facing each other with the bit line isolation portion interposed therebetween; forming bit lines filling the bit line openings to face each other with the bit line isolation portion interposed therebetween; forming a plurality of semiconductor lines perpendicular to the bit lines by etching the merged semiconductor line; forming a plurality of semiconductor pillars by etching the semiconductor lines in a direction perpendicular to the bit line; forming a body line commonly coupled to first sidewalls of the semiconductor pillars; forming a gate dielectric layer on second sidewalls of the semiconductor pillars; and forming a vertical word line over the gate dielectric layer. The forming of the body line commonly coupled to the first sidewalls of the semiconductor pillars may include forming a dielectric line between the semiconductor pillars; forming a first trench that exposes the first sidewalls of the semiconductor pillars by etching a portion of the dielectric line; and filling the first trench with a semiconductor material to form the body line. The body line may include silicon germanium. The vertical word line has a greater height than the body line. In the stacking of the sacrificial layer and the semiconductor layer over the substrate, the forming of the semiconductor layer may include depositing a P-type doped polysilicon layer; and exposing the P-type doped polysilicon layer to laser annealing to form a P-type doped monocrystalline silicon layer.

In accordance with still another embodiment of the present invention, a method for fabricating a semiconductor device may include forming a bit line over a substrate; forming a plurality of semiconductor pillars including first sidewalls and second sidewalls that are facing each other over the bit line; forming a body line which is commonly coupled to the first sidewalls of the semiconductor pillars; forming a gate dielectric layer on the second sidewalls of the semiconductor pillars; and forming a vertical word line facing the body line over the gate dielectric layer with the semiconductor pillars interposed therebetween. The body line may include silicon germanium. The forming of the body line which is commonly coupled to the first sidewalls of the semiconductor pillars may include forming a dielectric line between the semiconductor pillars; forming a first trench that exposes the first sidewalls of the semiconductor pillars by etching a portion of the dielectric line; filling the first trench with a semiconductor material; and trimming the semiconductor material to form the body line. The forming of the gate dielectric layer on the second sidewalls of the semiconductor pillars, and the forming of the vertical word line facing the body line over the gate dielectric layer with the semiconductor pillars interposed therebetween may include forming a dielectric line between the semiconductor pillars; forming a second trench that exposes the second sidewalls of the semiconductor pillars by etching a portion of the dielectric line; forming the gate dielectric layer on the exposed second sidewalls; and forming the vertical word line filling the second trench over the gate dielectric layer.

These and other advantages and features of the present invention will become better understood from the following detailed description and drawings.

### BRIEF DESCRIPTION OF THE DRAWINGS

FIG. 1 is a schematic perspective view illustrating a semiconductor device.

FIG. 2A is a schematic plan view illustrating a semiconductor device.

FIG. 2B is a cross-sectional view taken along line A-A′ of FIG. 2A.

FIG. 2C is a cross-sectional view taken along line B-B′ of FIG. 2A.

FIGS. 3 to 20 are cross-sectional views illustrating a method for fabricating a semiconductor device in accordance with an embodiment of the present invention.

FIG. 21 is a schematic perspective view illustrating a memory cell of a semiconductor device in accordance with embodiments of the present invention.

FIG. 22 is a schematic cross-sectional view illustrating the memory cell shown in FIG. 21.

FIG. 23 is a cross-sectional view illustrating a semiconductor device in accordance with another embodiment of the present invention.

FIG. 24 is a cross-sectional view illustrating a semiconductor device in accordance with another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and, in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

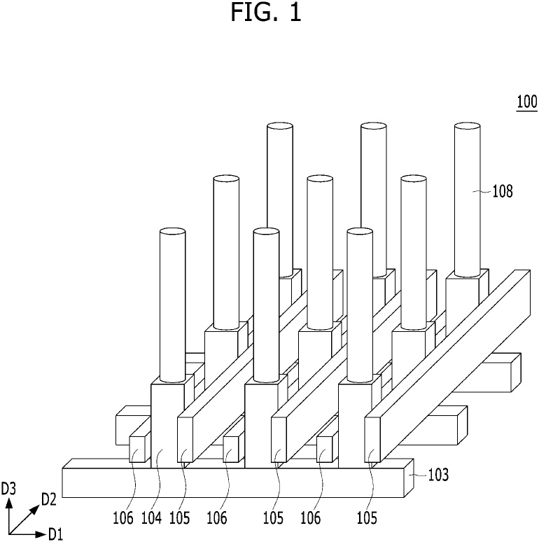

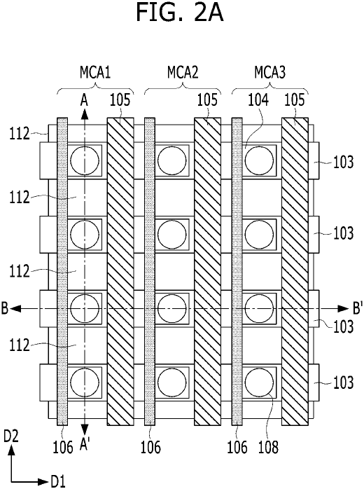

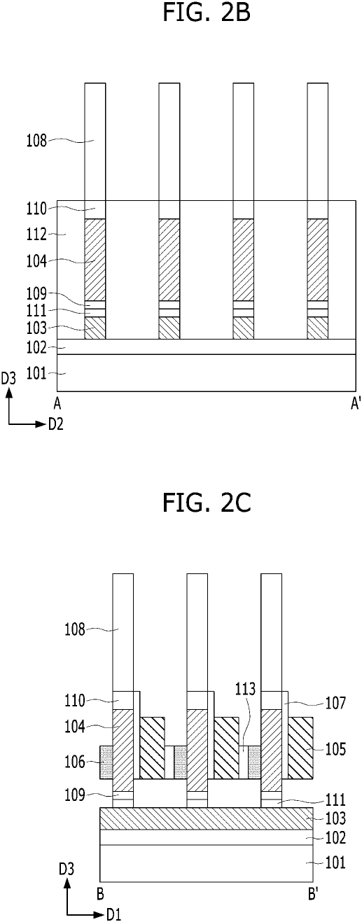

FIG. 1 is a schematic perspective view illustrating a semiconductor device. FIG. 2A is a schematic plan view illustrating a semiconductor device. FIG. 2B is a cross-sectional view taken along line A-A′ of FIG. 2A. FIG. 2C is a cross-sectional view taken along line B-B′ of FIG. 2A.

Referring to FIGS. 1 to 2C, the semiconductor device 100 shows a memory cell having a 4F2 (where F stands for the minimum feature size) structure.

The semiconductor device 100 may include a substrate 101, a buffer layer 102 over the substrate 101, a bit line 103 over the buffer layer 102, a vertical channel transistor over the bit line 103, and a capacitor 108 over the vertical channel transistor. The vertical channel transistor may include a semiconductor pillar 104, and a vertical word line 105 and a body line 106 that are disposed over both sidewalls of the semiconductor pillar 104. The vertical channel transistor may further include a gate dielectric layer 107 formed between the semiconductor pillar 104 and the vertical word line 105. The semiconductor device 100 may include a lower doped layer 109 between the semiconductor pillar 104 and the bit line 103, an upper doped layer 110 between the semiconductor pillar 104 and the capacitor 108, and an ohmic contact layer 111 between the lower doped layer 109 and the bit line 103.

The substrate 101 may be a material appropriate for semiconductor processing. The substrate 101 may include a semiconductor substrate. The substrate 101 may be formed of a silicon-containing material. The substrate 101 may include silicon, monocrystalline crystal silicon, polysilicon, amorphous silicon, silicon germanium, monocrystalline silicon germanium, polycrystalline silicon germanium, carbon-doped silicon, a combination thereof, or a multi-layer thereof. The substrate 101 may include other semiconductor materials, such as germanium. The substrate 101 may include a III/V-group semiconductor substrate, for example, a compound semiconductor substrate such as gallium arsenide (GaAs). The substrate 101 may include a Silicon-On-Insulator (SOI) substrate.

The buffer layer 102 may include silicon oxide, silicon nitride, or a combination thereof. To reduce parasitic capacitance, the buffer layer 102 may be formed of silicon oxide. For example, the buffer layer 102 may include Tetra Ethyl Ortho Silicate (TEOS).

The bit line 103 may extend laterally in a first direction D1 over the buffer layer 102. The bit line 103 may include a metal-based material. The bit line 103 may include a metal, a metal nitride, a metal silicide, or a combination thereof. For example, the bit line 103 may include a tungsten layer.

The ohmic contact layer 111 may include a metal, a metal nitride, a metal silicide, or a combination thereof. For example, the ohmic contact layer 111 may include titanium silicide.

The semiconductor pillar 104 may include a semiconductor material. For example, the semiconductor pillar 104 may be a silicon layer. The lower doped layer 109 and the upper doped layer 110 may be formed of the same material as that of the semiconductor pillar 104. The lower doped layer 109 and the upper doped layer 110 may be referred to as ‘source/drain regions’. The lower doped layer 109 and the upper doped layer 110 may include a silicon layer, and it may be a doped silicon layer which is doped with an impurity. According to another embodiment of the present invention, the semiconductor pillar 104 may include an oxide semiconductor material. A dielectric line 112 may be disposed between the neighboring semiconductor pillars 104 in a second direction D2.

As described above, the semiconductor pillar 104 may extend vertically in a third direction D3 over the bit line 103. The ohmic contact layer 111, the lower doped layer 109, the semiconductor pillar 104, and the upper doped layer 110 may be vertically stacked over the bit line 103 in the mentioned order. A stack structure in which the lower doped layer 109, the semiconductor pillar 104 and the upper doped layer 110 are stacked in the mentioned order may be referred to as an ‘active pillar’.

A conductive line having a double structure may be disposed over a sidewall of the semiconductor pillar 104. The double-structure conductive line may include a vertical word line 105 and a body line 106. The vertical word line 105 and the bit line 103 may extend in a direction crossing each other. The body line 106 and the bit line 103 may also extend in a direction crossing each other. The vertical word lines 105 and the body lines 106 may extend laterally in the second direction D2. The semiconductor pillars 104 may be disposed between the vertical word lines 105 and the body lines 106.

The body line 106 may have a pillar-tied or body-tied structure meaning that the body line 106 may directly contact one sidewall of the semiconductor pillar 104. The vertical word line 105 may be disposed over another sidewall of the semiconductor pillar 104 with the gate dielectric layer 107 interposed therebetween. The body line 106 may have a lower height than the vertical word line 105. The bottom surface of the vertical word line 105 and the bottom surface of the body line 106 may be disposed at the same lateral level. The top surface of the vertical word line 105 may be disposed at a higher lateral level than the top surface of the body line 106.

The body line 106 may include a semiconductor material. The body line 106 and the semiconductor pillar 104 may be formed of the same material. The body line 106 may include silicon germanium. A body bias Vbb may be applied through the body line 106, thereby eliminating a floating body effect.

The vertical word line 105 may include a semiconductor material, a metal-based material, or a combination thereof. The vertical word line 105 may include tantalum nitride (TaN), titanium nitride (TiN), tungsten (W), tungsten nitride (WN), or a combination thereof.

The gate dielectric layer 107 may include silicon oxide, silicon nitride, silicon oxynitride, a high-k material, or a combination thereof.

A capacitor 108 may be formed over each of the semiconductor pillars 104.

A protective layer 113 may be formed between the vertical word line 105 and the body line 106 from the perspective of a B-B′ direction. The protective layer 113 may include a dielectric material.

Referring back to FIG. 2A, the semiconductor device 100 may include a plurality of memory cell arrays MCA1, MCA2, and MCA3. The memory cell arrays MCA1, MCA2, and MCA3 may be spaced apart from each other in the first direction D1. Each of the memory cell arrays MCA1, MCA2, and MCA3 may include a plurality of semiconductor pillars 104 that are arranged in the second direction D2. For example, an array of the semiconductor pillars 104 included in each of the memory cell arrays MCA1, MCA2, and MCA3 may share one body line 106.

The body line 106 and the vertical word line 105 may extend in the second direction D2. Each of the memory cell arrays MCA1, MCA2, and MCA3 may share one body line 106 and one vertical word line 105. The memory cell arrays MCA1, MCA2, and MCA3 may share a plurality of bit lines 103.

The semiconductor pillars 104 arranged in the second direction D2 may contact one body line 106.

According to the above-described embodiment of the present invention, since the body bias Vbb may be adjusted using the body line 106, the floating body effect may be eliminated.

The body lines 106 may be advantageous in terms of the symmetry of the semiconductor pillars 104. In other words, the semiconductor pillars 104 may be arranged with uniform spacing, thereby reducing the cell size. Also, the body lines 106 may prevent interference between the neighboring vertical word lines 105 disposed in the first direction D1.

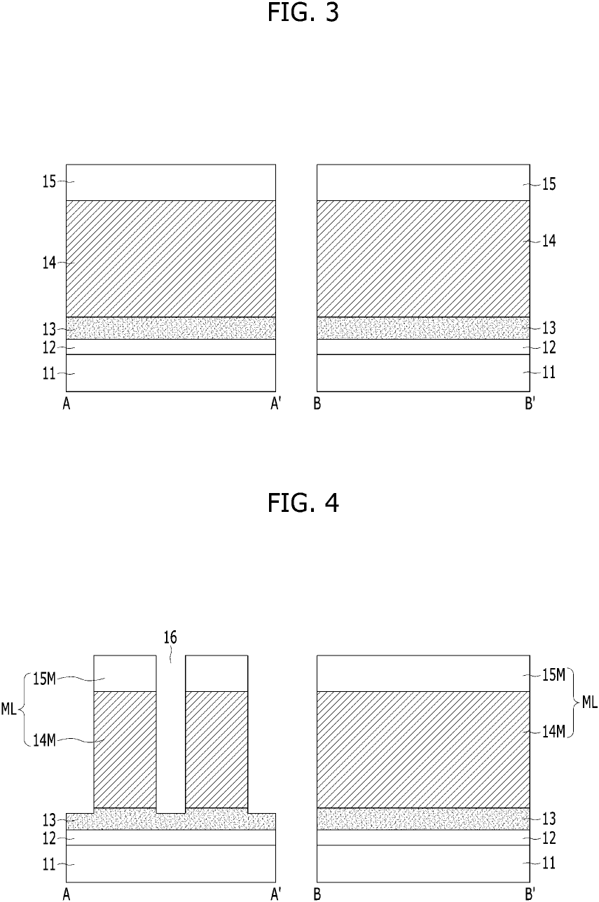

FIGS. 3 to 20 are cross-sectional views illustrating a method for fabricating a semiconductor device in accordance with an embodiment of the present invention. FIGS. 3 to 20 simultaneously illustrates the fabrication method according to the A-A′ and B-B′ lines shown in FIG. 2A.

Referring to FIG. 3, a buffer layer 12 may be formed over a substrate 11. The substrate 11 may be a material appropriate for semiconductor processing. The substrate 11 may include a semiconductor substrate. The substrate 11 may be formed of a silicon-containing material. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may include other semiconductor materials, such as germanium. The substrate 11 may include a III/V-group semiconductor substrate, for example, a compound semiconductor substrate such as GaAs. The substrate 11 may include a Silicon-On-Insulator (SOI) substrate. The buffer layer 12 may include a dielectric material. The buffer layer 12 may include silicon oxide, silicon nitride, or a combination thereof. According to the embodiment of the present invention, the buffer layer 12 may be silicon nitride. The buffer layer 12 may serve as an etch barrier to protect the substrate 11 from the subsequent processes.

A sacrificial layer 13 may be formed over the buffer layer 12. The sacrificial layer 13 may be a material to be replaced with a bit line in a subsequent process. The sacrificial layer 13 may include silicon oxide, silicon nitride, or a combination thereof. According to the embodiment of the present invention, the sacrificial layer 13 may be silicon oxide. The sacrificial layer 13 may include a low-k material.

A semiconductor layer 14 may be formed over the sacrificial layer 13. The semiconductor layer 14 may include a semiconductor material. The semiconductor layer 14 may include monocrystalline silicon. The semiconductor layer 14 may be doped with a P-type impurity, that is, the semiconductor layer 14 may be P-type doped monocrystalline silicon. The semiconductor layer 14 may be formed by depositing P-type doped polysilicon and then performing laser annealing. The laser annealing may convert the P-type doped polysilicon into P-type doped monocrystalline silicon.

Subsequently, a hard mask layer 15 may be formed over the semiconductor layer 14. The hard mask layer 15 may include silicon nitride.

Referring to FIG. 4, the hard mask layer 15 and the semiconductor layer 14 may be etched to form a plurality of first line structures ML. First trenches 16 may be formed between the first line structures ML. Each of the first line structures ML may include a stack of a merged semiconductor line 14M and a merged hard mask line 15M. The first trenches 16 may extend in one direction. The bottom surfaces of the first trenches 16 may extend partially inside the sacrificial layer 13 to partially recess the surface of the sacrificial layer 13.

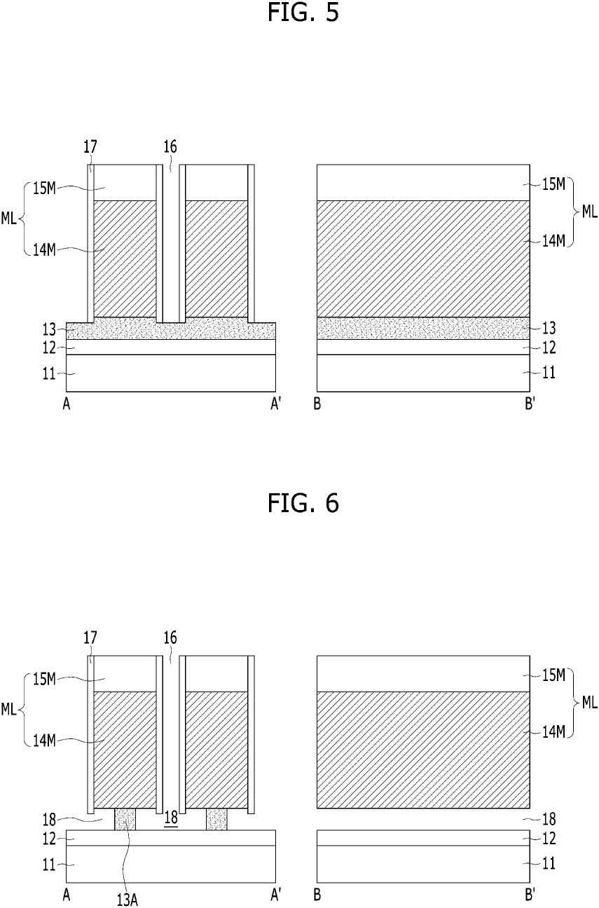

Referring to FIG. 5, spacers 17 may be formed on both sidewalls of the first line structures ML. The spacers 17 may include a dielectric material. The spacers 17 may be formed of a material having an etch selectivity with respect to the sacrificial layer 13. The spacers 17 may include silicon nitride. Deposition of silicon nitride and an etch-back process may be sequentially performed to form the spacers 17.

Referring to FIG. 6, the sacrificial layer 13 may be partially etched to form bit line openings 18. The partial etching of the sacrificial layer 13 may include wet etching. When the sacrificial layer 13 includes silicon oxide, the partial etching of the sacrificial layer 13 may include wet etching of silicon oxide. After the partial etching of the sacrificial layer 13, the remaining sacrificial layer may be simply referred to as a bit line isolation portion 13A. The bit line isolation portion 13A may be of silicon oxide. The bit line isolation portion 13A may be disposed below the merged semiconductor line 14M. The bit line openings 18 may be disposed between the merged semiconductor line 14M and the buffer layer 12 from the perspective of the B-B′ direction.

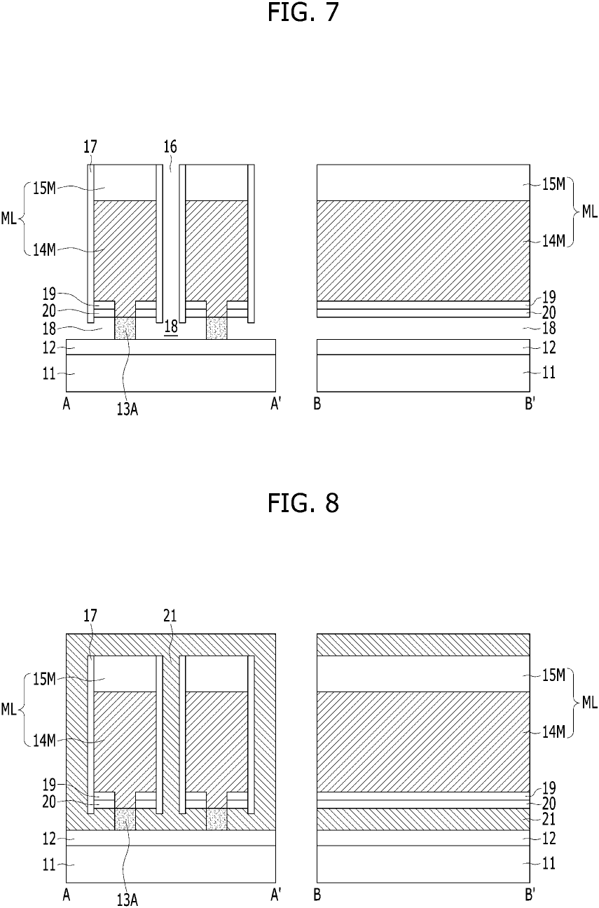

Referring to FIG. 7, lower doped layers 19 may be formed by a doping process. Plasma doping (PLAD) may be performed to form the lower doped layers 19. The N-type impurity may be doped by plasma doping (PLAD), and as a result, the lower doped layers 19 may be formed in the lower portion of the merged semiconductor line 14M. A pair of the lower doped layers 19 may be formed in one merged semiconductor line 14M. The pair of lower doped layers 19 may be formed to be spaced apart from each other by the width of the bit line isolation portion 13A. The plasma doping may be blocked by the merged hard mask line 15M and the spacer 17 in the upper portion and sidewalls of the merged bare conductor line 14M.

Ohmic contact layers 20 may be formed below the lower doped layers 19. The ohmic contact layers 20 may include a metal silicide. In order to form the ohmic contact layers 20, deposition of a metal layer, heat treatment, and removal of the residual metal layer may be sequentially performed. The ohmic contact layers 20 may include cobalt silicide. A pair of ohmic contact layers 20 may be formed to be spaced apart from each other by the width of the bit line isolation portion 13A.

Referring to FIG. 8, a conductive layer 21 may be deposited to fill the bit line openings 18. The conductive layer 21 may include a low-resistance metal-based material. The conductive layer 21 may include titanium nitride, tungsten, tungsten nitride, molybdenum, ruthenium, or a combination thereof. The conductive layer 21 may be formed by Chemical Vapor Deposition (CVD).

Referring to FIG. 9, the conductive layer 21 may be etched back to form a bit line 22. After the bit line 22 is formed, second trenches 23 may be defined between the first line structures ML.

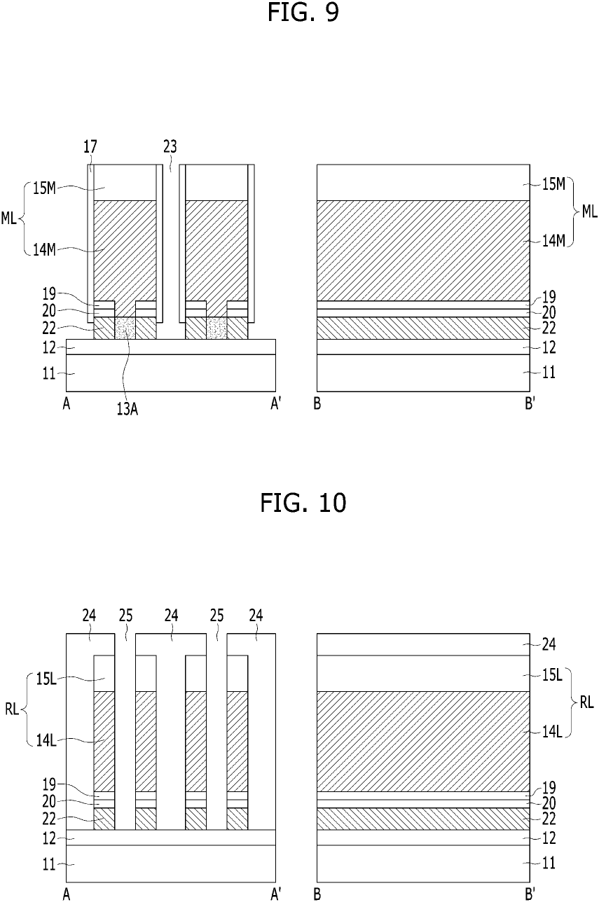

Referring to FIG. 10, after the spacers 17 are removed, first dielectric lines 24 filling the second trenches 23 may be formed. The first dielectric lines 24 may include silicon oxide. The first dielectric lines 24 may have a T-shape. The first dielectric lines 24 may include silicon oxide such as Spin-On-Dielectric (SOD). The first dielectric lines 24 may include a low-k material, thereby reducing parasitic capacitance between the neighboring bit lines 22.

A portion of the first line structures ML may be selectively etched to form third trenches 25. For example, the merged semiconductor lines 14M and the merged hard mask line 15M may be etched to form the second trenches 25. As a result, semiconductor lines 14L and hard mask lines 15L may be formed by the third trenches 25. The bit line isolation portions 13A may be removed during an etching process for forming the third trenches 25. Second line structures RL may be formed by the third trenches 25, and each of the second line structures RL may include a stack of the semiconductor line 14L and the hard mask line 15L. The third trenches 25 may extend in one direction. The bottom surfaces of the third trenches 25 may expose the surface of the buffer layer 12.

The ohmic contact layers 20 and the lower doped layers 19 may be disposed between the semiconductor lines 14L and the bit lines 22. A pair of the lower doped layers 19 may be isolated by the third trenches 25. A pair of the ohmic contact layers 20 may be isolated by the third trenches 25.

Referring to FIG. 11, a second dielectric line 26 filling the third trenches 25 may be formed. The second dielectric lines 26 may be formed by depositing a dielectric material and performing a planarization process. The first dielectric line 24 may be planarized during the planarization process to form the second dielectric lines 26. The first dielectric lines 24 and the second dielectric lines 26 may be alternately disposed between the semiconductor lines 14L. The neighboring bit lines 22 may be isolated from each other by the first dielectric lines 24 and the second dielectric lines 26.

The second dielectric lines 26 may include silicon oxide such as spin on dielectric (SOD). The second dielectric lines 26 may include a low-k material, which may reduce parasitic capacitance between the neighboring bit lines 22.

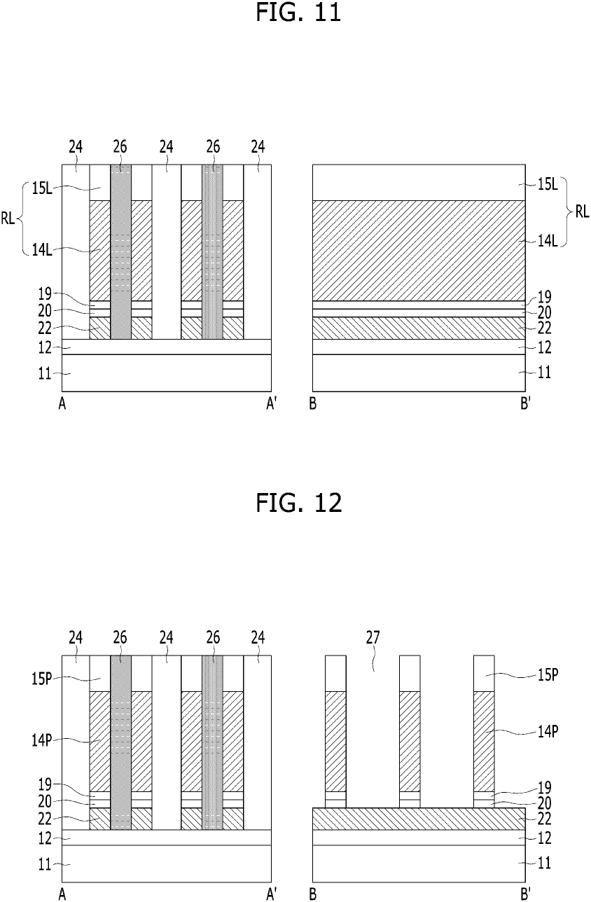

Referring to FIG. 12, fourth trenches 27 may be formed by etching the semiconductor lines 14L and the hard mask lines 15L in a direction crossing the bit line 22. Semiconductor pillars 14P and hard mask pillars 15P may be formed by the fourth trenches 27. The fourth trenches 27 and the bit lines 22 may cross each other.

A plurality of the semiconductor pillars 14P may be disposed over one bit line 22. The semiconductor pillars 14P may be disposed over the bit lines 22, respectively.

Referring to FIG. 13, third dielectric lines 28 filling the fourth trenches 27 may be formed. The third dielectric lines 28 may be formed by depositing a dielectric material and performing a planarization process. The third dielectric lines 28 may include silicon oxide. The semiconductor pillars 14P neighboring in the A-A′ direction may be isolated from each other by the first and second dielectric lines 24 and 26. The semiconductor pillars 14P neighboring in the B-B′ direction may be isolated from each other by the third dielectric lines 28. The third dielectric lines 28 may include silicon oxide, such as spin-on-dielectric (SOD). The third dielectric lines 28 may include a low-k material, which may reduce parasitic capacitance between the neighboring bit lines 22.

The first and second dielectric lines 24 and 26 may be disposed between the bit lines 22, and the third dielectric lines 28 may be disposed over the bit lines 22.

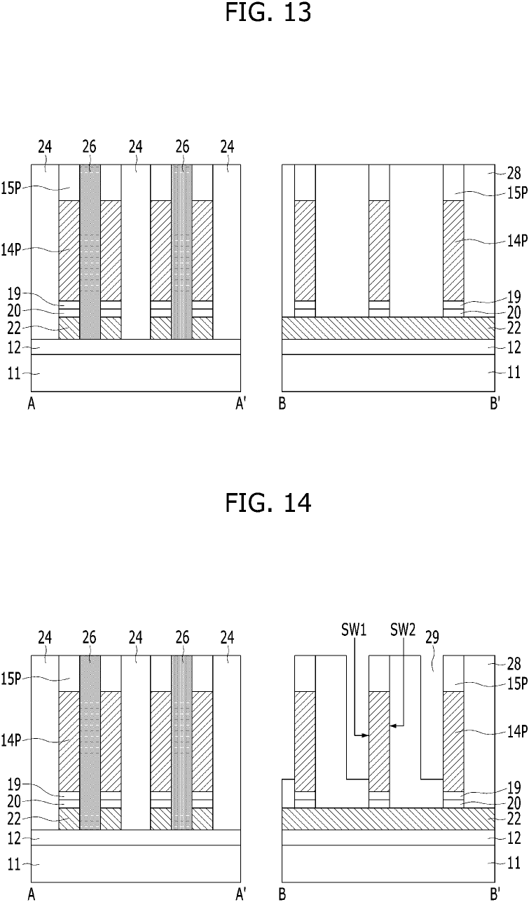

Referring to FIG. 14, the third dielectric lines 28 may be partially etched to form fifth trenches 29. The fifth trenches 29 may not pass through the third dielectric lines 28. For example, a portion of the third dielectric lines 28 may be disposed between the fifth trenches 29 and the bit line 22. From the perspective of the B-B′ direction, the fifth trenches 29 may simultaneously expose the first sidewalls SW1 of the semiconductor pillars 14P, and the second dielectric lines 28 may cover the second sidewalls SW2 of the semiconductor pillars 14P. The third dielectric lines 28 disposed between the semiconductor pillars 14P neighboring in the B-B′ direction may have an L-shape.

Referring to FIG. 15, an initial body line 30A may be formed on the exposed first sidewalls SW1 of the semiconductor pillars 14P. The initial body lines 30A may include a conductive material. The initial body lines 30A may include a semiconductor material. The initial body lines 30A and the semiconductor pillars 14P may be formed of different semiconductor materials. For example, the semiconductor pillars 14P may include silicon, and the initial body lines 30A may include silicon germanium. The initial body lines 30A may be formed by depositing a semiconductor material and performing an etch-back. The initial body lines 30A may be electrically connected to the first sidewalls SW1 of the semiconductor pillars 14P.

A capping layer 31 may be formed over each of the initial body lines 30A. The capping layer 31 may include silicon oxide, silicon nitride, or a combination thereof.

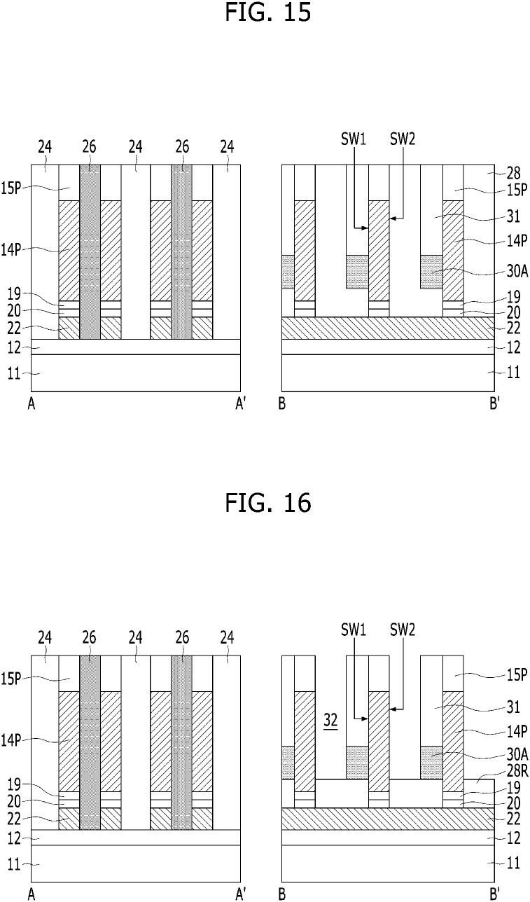

Referring to FIG. 16, sixth trenches 32 may be formed by etching other portions of the third dielectric lines 28. The sixth trenches 32 may simultaneously expose the second sidewalls SW2 of the semiconductor pillars 14P. Remaining portions of the third dielectric lines 28, that is, the third dielectric lines 28R may be disposed below the sixth trenches 32.

Referring to FIG. 17, the initial body lines 30A may be partially etched through the sixth trenches 32. Accordingly, body lines 30 may be formed. The etching process of the initial body lines 30A for forming the body lines 30 may be referred to as a trimming process. The etching process of the initial body lines 30A may include wet etching. For example, the wet etching process of the initial body lines 30A may be performed based on the difference in the wet etching rates between silicon and silicon germanium. In other words, the initial body lines 30A may be selectively etched without loss of the semiconductor pillars 14P based on the difference between the wet etch rate of silicon of the semiconductor pillars 14P and the wet etch rate of silicon germanium of the initial body lines 30A.

The body lines 30 may be electrically connected to the first sidewalls SW1 of the semiconductor pillars 14P. Referring to the body lines 106 of FIG. 2A, one body line 30 may share the semiconductor pillars 14P (see 104 of FIG. 2A) that are arranged in the second direction D2. In other words, one body line 30 may share one pillar array. Referring back to FIG. 2A, for example, an array of the semiconductor pillars 104 included in the memory cell array MCA1 may share one body line 106.

Consequently, the body lines 30 may be advantageous in terms of the symmetry of the semiconductor pillars 14P. In other words, the semiconductor pillars 14P may be arranged with uniform spacing, and thus the cell size may be reduced. Also, interference between the neighboring vertical word lines 35 may be prevented by the body lines 30.

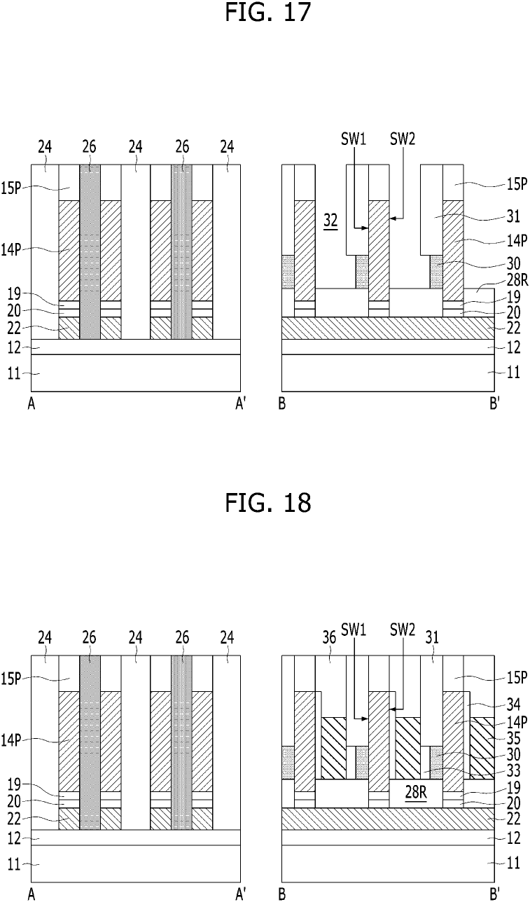

Referring to FIG. 18, a protective layer 33 may be formed over the body lines 30. The protective layer 33 may include a dielectric material. The protective layer 33 may include silicon oxide, silicon nitride, a low-k material, or a combination thereof. For example, in order to form the protective layer 33, a dielectric material may be deposited over the body lines 30 and then etched back. The protective layer 33 may be disposed below the capping layer 31.

Subsequently, a gate dielectric layer 34 may be formed on the exposed second sidewalls SW2 of the semiconductor pillars 14P. The gate dielectric layer 34 may be formed by a thermal oxidation process. The gate dielectric layer 34 may include silicon oxide, silicon nitride, silicon oxynitride, a high-k material, or a combination thereof. The high-k material may include a material having a greater dielectric constant than that of silicon oxide. For example, the high-k material may include a material having a greater dielectric constant than approximately 3.9. To take another example, the high-k material may include a material having a greater dielectric constant than approximately 10. As yet another example, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may be selectively used. The gate dielectric layer 34 may include a metal oxide.

A vertical word line 35 may be formed over the gate dielectric layer 34. The vertical word line 35A may partially fill the sixth trenches 32 over the gate dielectric layer 34. The vertical word line 35 may include a metal-based material. The vertical word line 35 may include a metal, a metal nitride, or a combination thereof. The vertical word line 35 may include tantalum nitride (TaN), titanium nitride (TiN), tungsten (W), ruthenium (Ru), tungsten nitride (WN), or a combination thereof.

A word line capping layer 36 may be formed over the vertical word line 35. The word line capping layer 36 may include silicon oxide, silicon nitride, a low-k material, or a combination thereof. For example, to form the word line capping layer 36, a dielectric material may be deposited over the vertical word line 35 and then planarized. The word line capping layer 36 may contact the sidewall of the hard mask pillar 15P and the capping layer 31.

The vertical word line 35 and the body line 30 may face each other with the semiconductor pillar 14P interposed therebetween. The vertical word line 35 and the body line 30 may cross the bit line 22.

Referring to FIG. 19, the hard mask pillars 15P may be selectively removed in order to expose the upper surfaces of the semiconductor pillars 14P. A planarization process may be performed to remove the hard mask pillars 15P, and the first and second dielectric lines 24 and 26, the capping layer 31, and the word line capping layer 36 may be planarized during the planarization process.

Subsequently, upper doped layers 37 may be formed in the upper region of the semiconductor pillars 14P. The upper doped layers 37 may be formed by a doping process, such as implantation or plasma doping. The upper doped layers 37 may be doped with an N-type impurity. The upper doped layers 37 and the lower doped layers 19 may be doped with impurities of the same conductivity type.

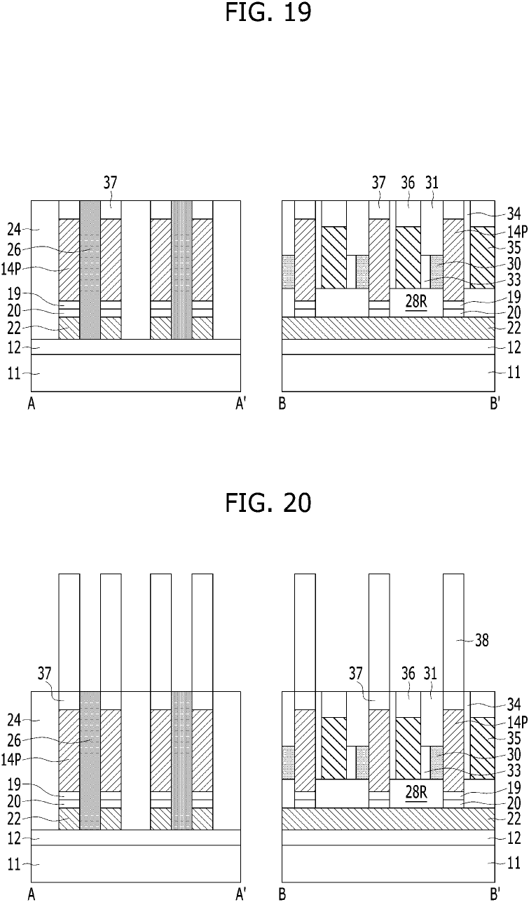

Referring to FIG. 20, a capacitor 38 may be formed over the upper doped layer 37.

As described above, the semiconductor device may include the semiconductor pillar 14P including the first sidewall SW1 and the second sidewall SW2 facing each other, and the bit line 22 coupled to the lower portion of the semiconductor pillar 14P, the capacitor 38 coupled to the upper portion of the semiconductor pillar 14P, the body line 30 coupled to the first sidewall SW1 of the semiconductor pillar 14P, and the vertical word line 35 disposed over the second sidewall SW2 of the semiconductor pillar 14P. The gate dielectric layer 34 may be disposed between the second sidewall SW2 of the semiconductor pillar 14P and the vertical word line 35.

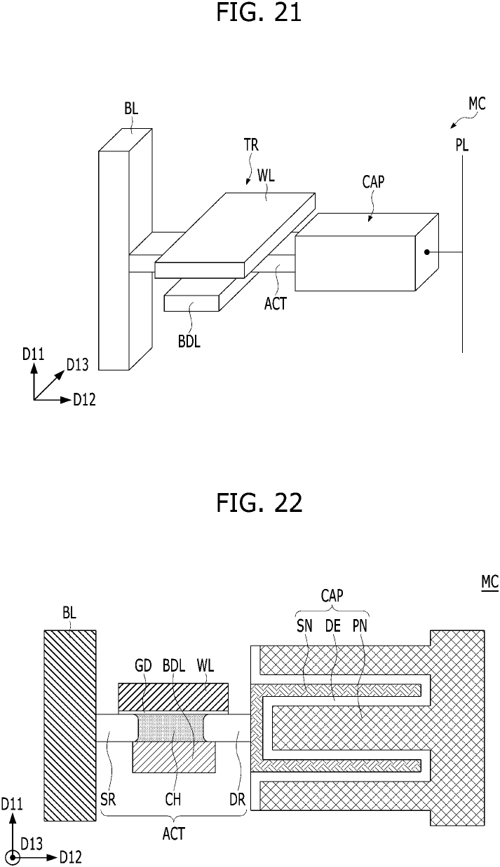

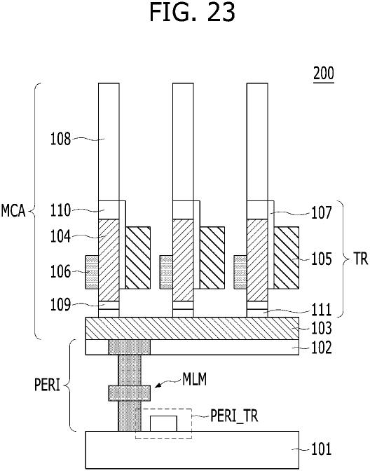

FIG. 21 is a schematic perspective view illustrating a memory cell of a semiconductor device in accordance with embodiments of the present invention. FIG. 22 is a schematic cross-sectional view illustrating the memory cell shown in FIG. 21.

Referring to FIGS. 21 and 22, the memory cell MC of a 3D semiconductor device according to the embodiments of the present invention may include a bit line BL, a transistor TR, and a capacitor CAP. The transistor TR may include an active layer ACT, a word line WL, and a body line BDL, and the word line WL and the body line BDL may face each other with the active layer ACT interposed therebetween. The capacitor CAP may include a storage node SN, a dielectric layer DE, and a plate node PN.

The bit line BL may have a pillar shape extending vertically in the first direction D11. The active layer ACT may have a bar shape extending laterally in the second direction D12 crossing the first direction D11. The word line WL may have a line shape extending laterally in the third direction D13 crossing the first and second directions D11 and D12. The plate node PN of the capacitor CAP may be coupled to the plate line PL.

The bit line BL may be vertically oriented in the first direction D11. The bit line BL may be referred to as a vertically oriented bit line or a pillar-type bit line. The bit line BL may include a conductive material. The bit line BL may include a silicon-based material, a metal-based material, or a combination thereof. The bit line BL may include silicon, a metal, a metal nitride, a metal silicide, or a combination thereof. The bit line BL may include polysilicon, titanium nitride, tungsten, or a combination thereof. For example, the bit line BL may include polysilicon or titanium nitride (TiN) which is doped with an N-type impurity. The bit line BL may include a TiN/W stack including titanium nitride and tungsten over the titanium nitride.

A gate dielectric layer GD may be formed on the upper surface of the active layer ACT.

The active layer ACT may include a semiconductor material or an oxide semiconductor material. For example, the active layer ACT may include monocrystalline silicon, germanium, silicon-germanium, or indium gallium zinc oxide (IGZO). The active layer ACT may include polysilicon or monocrystalline silicon. The active layer ACT may include a channel CH, a first source/drain region SR between the channel CH and the bit line BL, and a second source/drain region DR between the channel CH and the capacitor CAP. The channel CH may be defined between the first source/drain region SR and the second source/drain region DR.

The body line BDL may include silicon germanium. The body line BDL may directly contact the channel CH of the active layer ACT, thereby eliminating the floating body effect.

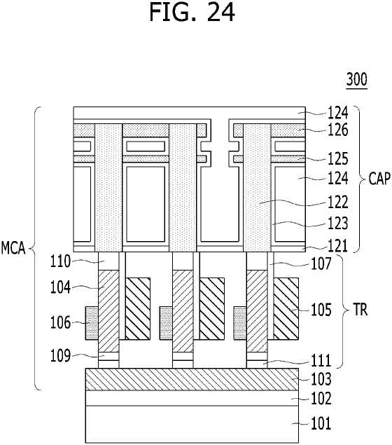

FIG. 23 is a cross-sectional view illustrating a semiconductor device in accordance with another embodiment of the present invention.

The semiconductor device 200 of FIG. 23 may be similar to the semiconductor device 100 of FIGS. 1 to 2C. Hereinafter, descriptions on the components also appearing in FIGS. 1 to 2C will be omitted.

Referring to FIG. 23, the semiconductor device 200 may include a substrate 101, a peripheral circuit portion PERI disposed over the substrate 101, and a memory cell array MCA disposed over the peripheral circuit portion PERI. The memory cell array MCA may include a bit line 103, a transistor TR, and a capacitor 108.

The transistor TR may include a semiconductor pillar 104 disposed between the bit line 103 and the capacitor 108, a vertical word line 105 disposed over the first sidewall of the semiconductor pillar 104, and a body line 106 coupled to the second sidewall of the semiconductor pillar 104. The body line 106 may include silicon germanium. A gate dielectric layer 107 may be disposed between the vertical word line 105 and the pillar 104. The body line 106 may directly contact the sidewall of the semiconductor pillar 104.

A lower doped layer 109 and an ohmic contact layer 111 may be formed below the semiconductor pillar 104, and an upper doped layer 110 may be formed over the semiconductor pillar 104.

The peripheral circuit portion PERI may include a peripheral circuit transistor PERI_TR and a multi-level metal interconnection MLM. The uppermost metal interconnection of the multi-layer level metal interconnection MLM may pass through the buffer layer 102 to be coupled to the bit line 103.

FIG. 24 is a cross-sectional view illustrating a semiconductor device in accordance with another embodiment of the present invention.

The semiconductor device 300 of FIG. 24 may be similar to the semiconductor device 100 of FIGS. 1 to 2C. Hereinafter, descriptions on the components also appearing in FIGS. 1 to 2C will be omitted.

Referring to FIG. 24, the semiconductor device 300 may include a substrate 101, a bit line 103 over the substrate 101, and a memory cell array MCA including a transistor TR and a capacitor CAP.

The transistor TR may include a semiconductor pillar 104 disposed between the bit line 103 and the capacitor CAP, a vertical word line 105 disposed over a first sidewall of the semiconductor pillar 104, and a body line 106 coupled to a second sidewall of the semiconductor pillar 104. The body line 106 may include silicon germanium. A gate dielectric layer 107 may be disposed between the vertical word line 105 and the semiconductor pillar 104. A lower doped layer 109 and an ohmic contact layer 111 may be formed below the semiconductor pillar 104, and an upper doped layer 110 may be formed over the semiconductor pillar 104.

The capacitor CAP may include a lower electrode 122, a dielectric layer 123, and an upper electrode 124. The lower electrode 122 may have a pillar shape. The lower electrode 122 may be supported by multi-layer level supporters 125 and 126. A sidewall of the bottom portion of the lower electrode 122 may contact the etch stop layer 121. The lower electrode 122 may contact the upper doped layer 110 of the transistor TR.

According to the embodiment of the present invention, a floating body effect may be removed by forming a body line which is in direct contact with a sidewall of a semiconductor pillar.

The effects desired to be obtained in the embodiments of the present invention are not limited to the effects mentioned above, and other effects not mentioned above may also be clearly understood by those of ordinary skill in the art to which the present invention pertains from the description below.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a semiconductor pillar including a first sidewall and a second sidewall facing each other;
a bit line coupled to a lower portion of the semiconductor pillar;
a capacitor coupled to an upper portion of the semiconductor pillar;
a body line coupled to the first sidewall of the semiconductor pillar; and
a vertical word line disposed over the second sidewall of the semiconductor pillar.

2. The semiconductor device of claim 1, wherein the vertical word line and the body line extend while facing each other with the semiconductor pillar interposed therebetween.

3. The semiconductor device of claim 1, wherein the body line includes a semiconductor material.

4. The semiconductor device of claim 1, wherein the body line includes silicon germanium.

5. The semiconductor device of claim 1, wherein the vertical word line has a greater height than the body line.

6. The semiconductor device of claim 1, further comprising:
a gate dielectric layer between the semiconductor pillar and the vertical word line.

7. The semiconductor device of claim 1, further comprising:
a dielectric layer between the bit line and the vertical word line.

8. The semiconductor device of claim 1, wherein the semiconductor pillar includes monocrystalline silicon.

9. The semiconductor device of claim 1,
wherein a plurality of the semiconductor pillars are disposed in a direction that the bit line extends, the body line is coupled to each of the first sidewalls of the semiconductor pillars, and the vertical word line is disposed over each of the second sidewalls of the semiconductor pillars located, and
wherein the semiconductor pillars further include a protective layer between the body lines and the vertical word lines.

10. A semiconductor device comprising:
a substrate;
a peripheral circuit portion over the substrate; and
a memory cell array including a bit line, a transistor, and a capacitor that are vertically stacked with respect to the peripheral circuit portion,
wherein the transistor includes:
a semiconductor pillar disposed between the bit line and the capacitor;
a body line coupled to a first sidewall of the semiconductor pillar; and
a vertical word line disposed over a second sidewall of the semiconductor pillar.

11. The semiconductor device of claim 10, wherein the vertical word line and the body line extend while facing each other with the semiconductor pillar interposed therebetween.

12. The semiconductor device of claim 10, wherein the body line includes silicon germanium.

13. The semiconductor device of claim 10, wherein the vertical word line has a greater height than the body line.

14. The semiconductor device of claim 10, further comprising:
a gate dielectric layer between the semiconductor pillar and the vertical word line.

15. The semiconductor device of claim 10, wherein the semiconductor pillar includes monocrystalline silicon.

16. The semiconductor device of claim 10, wherein the peripheral circuit portion is disposed at a lower level than the memory cell array or disposed at a higher level than the memory cell array.

17. The semiconductor device of claim 10,
wherein a plurality of the semiconductor pillars are disposed in a direction that the bit line extends, the body line is coupled to each of the first sidewalls of the semiconductor pillars, and the vertical word line is disposed over each of the second sidewalls of the semiconductor pillars located, and
wherein the semiconductor pillars further include a protective layer between the body lines and the vertical word lines.
